(19) United States
(12) Patent Application Publication
(10) Pub. No.: US 2015/0179446 A1
(43) Pub. Date: Jun. 25, 2015

(54) Methods for Forming Crystalline IGZO Through Processing Condition Optimization

(71) Applicants: LG DISPLAY CO., LTD., Seoul (KR); INTERMOLECULAR, INC., San Jose, CA (US)

(72) Inventors: Sang Lee, San Jose, CA (US); Stuart Brinkley, Sunnyvale, CA (US); Yoon-Kyung Chang, Gyeonggi-do (KR); Seon-Mee Cho, Santa Clara, CA (US); Min-Cheol Kim, Gyeonggi-do (KR); Kwon-Sik Park, Gangnam-gu (KR); Woosup Shin, Gyeonggi-do (KR)

(73) Assignees: LG DISPLAY CO., LTD., Seoul (KR); INTERMOLECULAR, INC., San Jose, CA (US)

(21) Appl. No.: 14/137,749

(22) Filed: Dec. 20, 2013

(51) Int. Cl. H01L 21/02; H01L 29/66; H01L 29/786

(52) U.S. Cl. CPC H01L 21/02595; H01L 21/02565; H01L 21/02667; H01L 29/7869; H01L 29/66969

(57) ABSTRACT

Embodiments described herein provide method for forming crystalline indium-gallium-zinc oxide (IGZO). A substrate is provided. A layer is formed above the substrate using a PVD process. The layer includes indium, gallium, zinc, or a combination thereof. The PVD process is performed in a gaseous environment having a pressure of between about 1 mT and about 5 mT and including between about 20% and about 100% oxygen gas. The PVD process may be performed at a processing temperature between about 25° C. and about 400° C. The duty cycle of the PVD process may be between about 70% and about 100%.

### TECHNICAL FIELD

The present invention relates to indium-gallium-zinc oxide (IGZO). More particularly, this invention relates to methods for forming crystalline IGZO, as well as methods for forming IGZO devices, such as IGZO thin film transistors (TFTs), incorporating crystalline IGZO.

### BACKGROUND OF THE INVENTION

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light display applications. Due to these attributes, IGZO TFTs may even be favored over low cost amorphous silicon TFTs and relatively high mobility polycrystalline silicon TFT for display device applications. IGZO devices typically utilize amorphous IGZO (a-IGZO).

Recent developments in the field suggest that the use of crystalline IGZO may provide improved electrical and chemical stability. However, little work has been done to determine how to form crystalline IGZO, or convert a-IGZO to crystalline IGZO, using already-existing manufacturing and processing equipment.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with an indium-gallium-zinc oxide (IGZO) channel layer formed above the gate dielectric layer.

FIG. 4 is a cross-sectional view of the substrate of FIG. 3 with an etch-stop layer formed above the IGZO layer.

FIG. 5 is a cross-sectional view of the substrate of FIG. 4 with source and drain regions formed above the etch-stop layer.

FIG. 6 is a cross-sectional view of the substrate of FIG. 5 with a passivation layer formed above the source and drain regions.

FIG. 7 is a graph depicting X-ray diffraction (XRD) crystalline peak heights of IGZO formed using a physical vapor deposition (PVD) process performed at various chamber pressures.

FIG. 8 is a graph depicting XRD crystalline peak heights of IGZO formed using a PVD process performed with various oxygen incorporation rates.

FIG. 9 is a graph depicting XRD crystalline peak heights of IGZO formed using a PVD process performed using various duty cycles.

FIG. 10 is a graph depicting XRD crystalline peak heights of IGZO formed using a PVD process performed at various processing temperatures.

FIG. 11 is a simplified cross-sectional diagram illustrating a PVD tool according to some embodiments.

FIG. 12 is a flow chart illustrating a method for forming crystalline IGZO according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide methods for improving the electrical and chemical stability of indium-gallium-zinc oxide (IGZO). In particular, embodiments described herein methods for enhancing the crystalline structure of the IGZO along the c-axis (i.e., along the (009) plane, which is in the direction perpendicular to the substrate), which improves the electrical and chemical stability of the IGZO.

In some embodiments, this is accomplished by depositing the IGZO using a physical vapor deposition (PVD) process, such as sputtering, using particular processing conditions with respect to, for example, the pressure within the processing chamber of the PVD tool, the oxygen incorporation rate (i.e., the percentage of oxygen) within the processing chamber, the “duty cycle” of the PVD process (e.g., the portion of the process the charge on the PVD target(s) is negative), and the processing temperature.

In some embodiments, the pressure within the processing chamber of the PVD tool is maintained at less than about 5 millitorr (mT), such as between about 1 mT and about 5 mT. In some embodiments, the oxygen incorporation rate within the processing chamber is maintained at between about 20% and about 100% during the deposition process. In some embodiments, the duty cycle of the PVD process is maintained between about 70% and 100%. In some embodiments, the processing temperature is maintained between room temperature (e.g., about 25° C.) and about 400° C. These PVD processing conditions may be used either individually or in any combination and causes the IGZO to be deposited (or grown) with an enhanced crystalline structure along the c-axis. The IGZO may be formed as a channel (or channel layer) in an IGZO thin-film transistor (TFT).

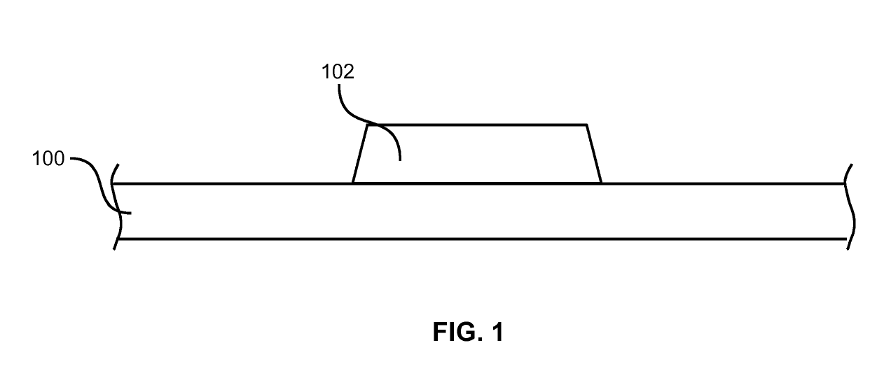

FIGS. 1-6 illustrate a method for forming an IGZO thin film transistor (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between 0.01 and 0.5 centimeters (cm). Although only a portion of the substrate 100 is shown, it should be understood that the substrate 100 may have a width of, for example, between 5.0 cm and 4.0 meters (m). Although not shown, in some embodiments, the substrate 102 may have a dielectric layer (e.g., silicon oxide) formed above an upper surface thereof. In such embodiments, the components described below are formed above the dielectric layer.

Still referring to FIG. 1, a gate electrode 102 is formed above the transparent substrate 100. In some embodiments, the gate electrode 102 is made of a conductive material, such as copper, silver, aluminum, manganese, molybdenum, or a combination thereof. The gate electrode may have a thickness of, for example, between about 20 nanometers (nm) and about 500 nm. Although not shown, it should be understood that in some embodiments, a seed layer (e.g., a copper alloy) is formed between the substrate 100 and the gate electrode 102.

It should be understood that the various components on the substrate, such as the gate electrode 102 and those described below, are formed using processing techniques suitable for the particular materials being deposited, such as PVD (e.g., co-sputtering in some embodiments), chemical vapor deposition (CVD), electroplating, etc. Furthermore, although not specifically shown in the figures, it should be understood that the various components on the substrate 100, such as the gate electrode 102, may be sized and shaped using a photolithography process and an etching process, as is commonly understood, such that the components are formed above selected regions of the substrate 100.

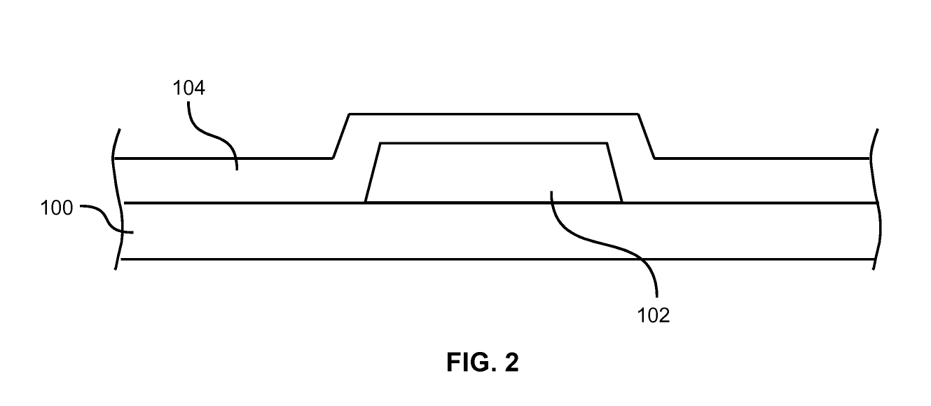

Referring to FIG. 2, a gate dielectric layer 104 is then formed above the gate electrode 102 and the exposed portions of the substrate 100. The gate dielectric layer 104 may be made of, for example, silicon oxide, silicon nitride, or a high-k dielectric (e.g., having a dielectric constant greater than 3.9), such as zirconium oxide, hafnium oxide, or aluminum oxide. In some embodiments, the gate dielectric layer 104 has a thickness of, for example, between about 10 nm and about 500 nm.

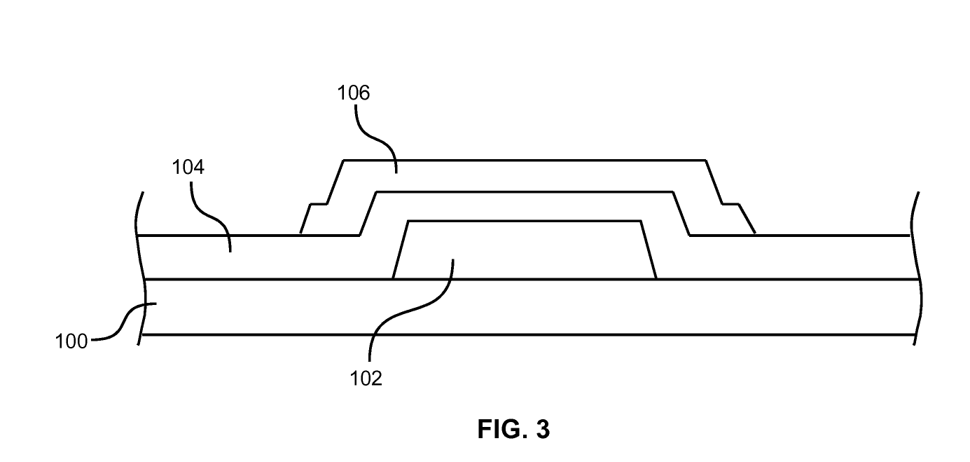

As shown in FIG. 3, an IGZO channel layer (or active layer) 106 is then formed above the gate dielectric layer 104, over the gate electrode 102. The IGZO channel layer 106 may be made of IGZO in which a ratio of the respective elements is 1:1:1:1-3. The IGZO channel layer 106 may have a thickness of, for example, between about 10 nm and about 100 nm.

The IGZO channel layer 106 (or at least the IGZO layer from which the IGZO channel layer 106 is formed), perhaps along with some of the other components described, may be formed using a PVD process (e.g., sputtering), using particular processing conditions. In some embodiments, the processing condition(s) include, for example, the pressure within the processing chamber of the PVD tool, the oxygen incorporation rate (i.e., the percentage of oxygen) within the processing chamber, the “duty cycle” of the PVD process (e.g., the portion of the process the charge on the PVD target(s) is negative), and the processing temperature.

In some embodiments, during the formation (or deposition) of the IGZO, the pressure within the processing chamber of the PVD tool is maintained at less than about 5 mT, such as between about 1 mT and about 5 mT. In some embodiments, the oxygen incorporation rate within the processing chamber is maintained at between about 20% and about 100% during the deposition process. In some embodiments, the processing temperature is maintained between room temperature (e.g., about 25° C.) and about 400° C. during the deposition of the IGZO.

In some embodiments, the duty cycle of the PVD process is maintained between about 70% and 100% during the deposition of the IGZO. As will be appreciated by one skilled in the art, the duty cycle of the PVD process may refer to the portion of the time of the deposition process during which a negative charge is applied to the PVD target(s). That is, in some embodiments, during the deposition process, the charge on the target(s) is alternated between a negative charge (e.g., about −300 V) and a non-negative charge (e.g., a positive charge, such as about +20 V). If the PVD tool is operated at a duty cycle of, for example, 70%, during the deposition process, the charge applied to the target(s) is negative, in total, for 70% of the time. One skilled in the art will appreciate that in such an embodiment, the charge may be switched at a frequency of, for example, between about 50 hertz (Hz) and about 13.56 megahertz (MHz), such as during operation using a alternating current (AC) power mode. If the PVD tool is operated at a duty cycle of 100%, the charge on the target(s) is negative throughout the deposition process. Such a manner of operation may be considered to be a direct current (DC) power mode.

The PVD processing conditions described above may be used either individually or in any combination and, as described below, each causes the IGZO to be deposited (or grown) with an enhanced crystalline structure along the c-axis.

In some embodiments, the IGZO is deposited from a single target that includes indium, gallium, and zinc (e.g., an indium-gallium-zinc alloy target or an IGZO target), while in some embodiments, two or more targets are used (e.g., co-sputtering with an indium-zinc target and a gallium target).

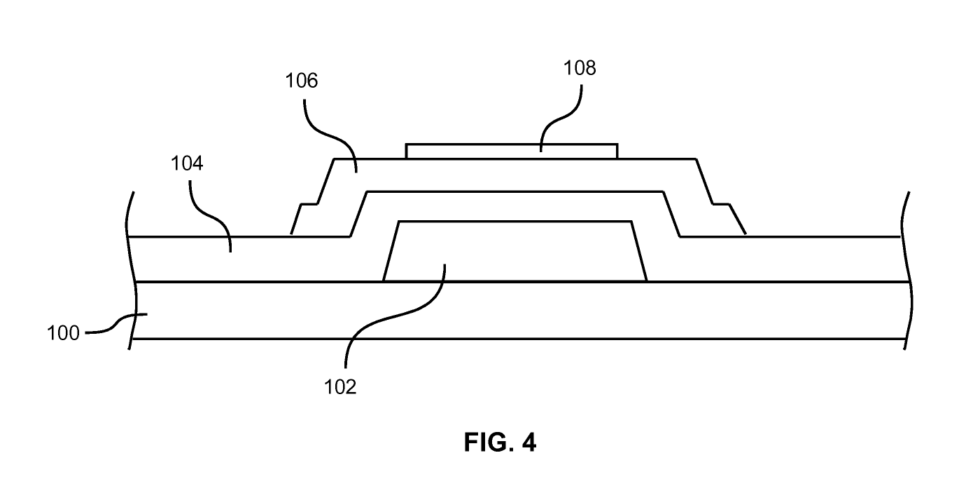

Although not specifically shown, in some embodiments, the IGZO channel layer 106 (and the other components shown in FIG. 4) may then undergo an annealing process. In some embodiments, the annealing process includes a relatively low temperature (e.g., less than about 600° C., preferably less than about 450° C.) heating process in, for example, an ambient gaseous environment (e.g., nitrogen, oxygen, or ambient/air) to further enhance the crystalline structure of the IGZO. The heating process may occur for between about 1 minute and about 200 minutes.

Referring now to FIG. 4, an etch-stop layer 108 is then formed above the IGZO channel layer 106. In some embodiments, the etch-stop layer 108 is made of a high-k dielectric, such as aluminum oxide and/or hafnium oxide. The etch-stop layer 108 may have a thickness of, for example, between about 10 nm and about 500 nm. It should be understood that in some embodiments, a conventional etch-stop layer is not formed above the IGZO channel layer 106, but rather the source and drain regions (described below) are selectively etched using a “back-channel etch” (BCE) process, as is commonly understood.

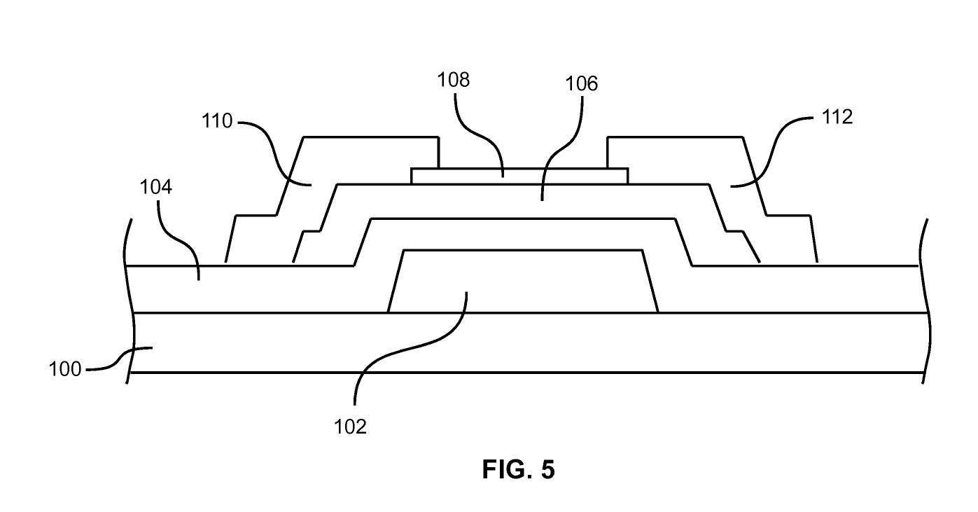

Next, as shown in FIG. 5, a source region (or electrode) 110 and a drain region (or electrode) 112 are formed above the IGZO channel layer 106. As shown, the source region 110 and the drain region 112 lie on opposing sides of, and partially overlap the ends of, the etch-stop layer 108 (which may be used to protect the IGZO channel layer 106 during an etch process used to define the source region 110 and the drain region 112). In some embodiments, the source region 110 and the drain region 112 are made of titanium, molybdenum, copper, copper-manganese alloy, or a combination thereof. The source region 110 and the drain regions 112 may have a thickness of, for example, between about 20 nm and 500 nm.

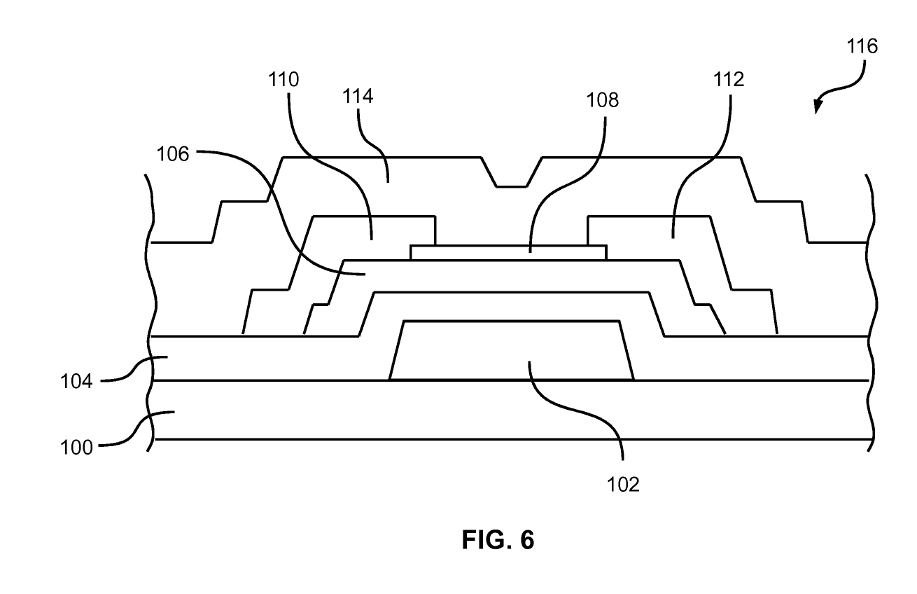

Referring to FIG. 6, a passivation layer 114 is then formed above the source region 110, the drain region 112, the etch-stop layer 108, and the gate dielectric layer 104. In some embodiments, the passivation layer 114 is made of silicon oxide, silicon nitride, aluminum oxide, aluminum nitride, or a combination thereof and has a thickness of, for example, between about 0.1 μm and about 1.5 μm.

The deposition of the passivation layer 114 may substantially complete the formation of an IGZO device 116, such as an inverted, staggered bottom-gate IGZO TFT. It should be understood that although only a single device 116 is shown as being formed on a particular portion of the substrate 100 in FIGS. 1-6, the manufacturing processes described above may be simultaneously performed on multiple portions of the substrate 100 such that multiple devices 116 are simultaneously formed, as is commonly understood.

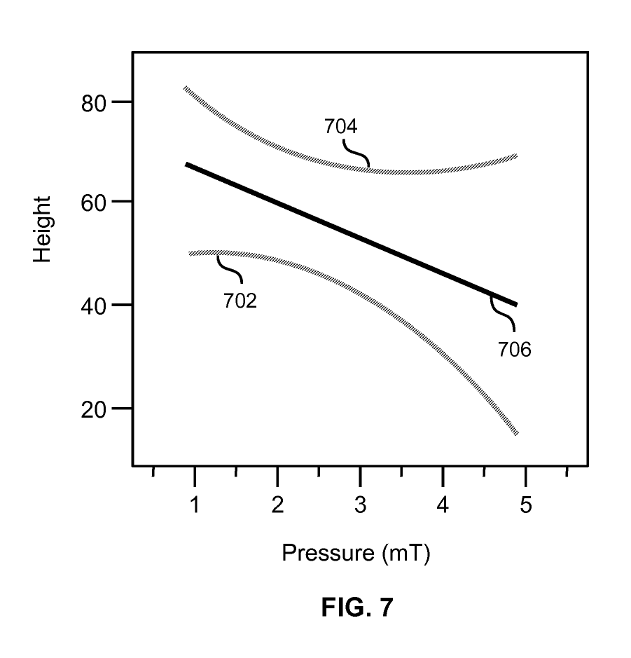

FIG. 7 graphically illustrates the X-ray diffraction (XRD) scattering intensity of the (009) crystalline peak in IGZO deposited using PVD at chamber pressures (mT), such as about 1 mT to about 5 mT. At each pressure, line 702 depicts a lower bound of the resulting scattering intensity, line 704 depicts a upper bound of the scattering intensity, and line 706 depicts the mean (or average) scattering intensity. As shown, as the pressure is decreased, at least from 5 mT to 1 mT, the scattering of the (009) crystalline peak increases. Thus, in general, decreasing the chamber pressure enhances the crystalline structure along the (009) plane.

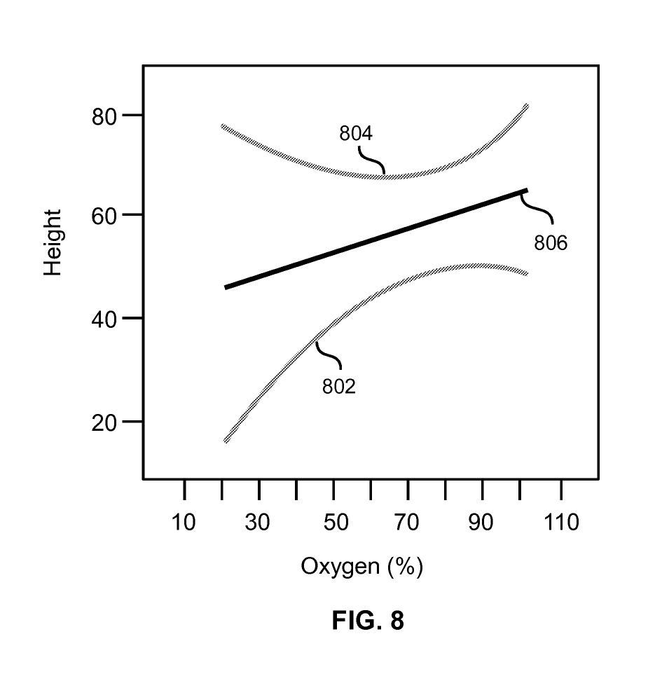

FIG. 8 graphically illustrates the XRD scattering intensity of the (009) crystalline peak in IGZO deposited using PVD at various oxygen incorporation rates (%), such as about 20% to about 100%. At each oxygen incorporation rate, line 802 depicts a lower bound of the resulting scattering intensity, line 804 depicts a upper bound of the scattering intensity, and line 806 depicts the mean (or average) scattering intensity. As shown, as the oxygen incorporation rate is increased, the scattering of the (009) crystalline peak also increases. Thus, in general, increasing the oxygen incorporation rate within the PVD chamber enhances the crystalline structure along the (009) plane.

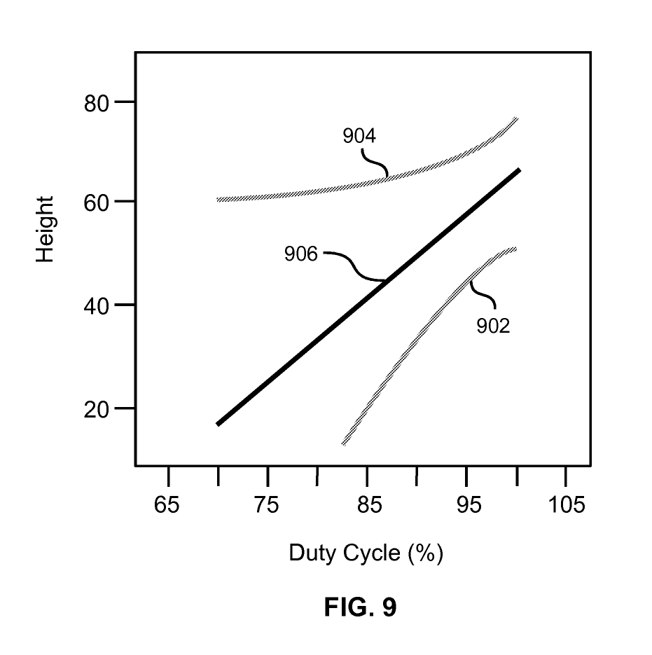

FIG. 9 graphically illustrates the XRD scattering intensity of the (009) crystalline peak in IGZO deposited using a PVD process with various duty cycles (%), such as about 70% to about 100%. At each duty cycle, line 902 depicts a lower bound of the resulting scattering intensity, line 904 depicts a upper bound of the scattering intensity, and line 906 depicts the mean (or average) scattering intensity. As shown, as the duty cycle is increased, the scattering of the (009) crystalline peak also increases. Thus, in general, increasing the duty cycle of the PVD process enhances the crystalline structure along the (009) plane.

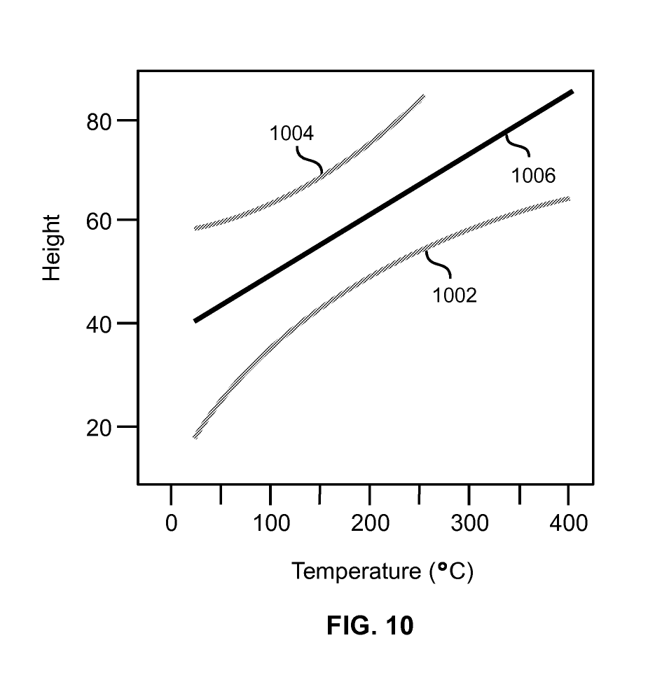

FIG. 10 graphically illustrates the XRD scattering intensity of the (009) crystalline peak in IGZO deposited using PVD at various processing temperatures (° C.), such as about 25° C. to about 400° C. At each processing temperature, line 1002 depicts a lower bound of the resulting scattering intensity, line 1004 depicts a upper bound of the scattering intensity, and line 1006 depicts the mean (or average) scattering intensity. As shown, as the processing temperature is increased, the scattering of the (009) crystalline peak also increases. Thus, in general, increasing the processing temperature within the PVD processing chamber enhances the crystalline structure along the (009) plane.

The enhanced crystalline structure of the IGZO may improve both the electrical and chemical stability of the IGZO. When utilized in an IGZO device, such as the IGZO TFT described above, the crystalline IGZO may improve device performance, especially with respect to reliability and longevity. Additionally, it should be noted that the methods described herein may be easily incorporated into already-existing IGZO device manufacturing processes and equipment.

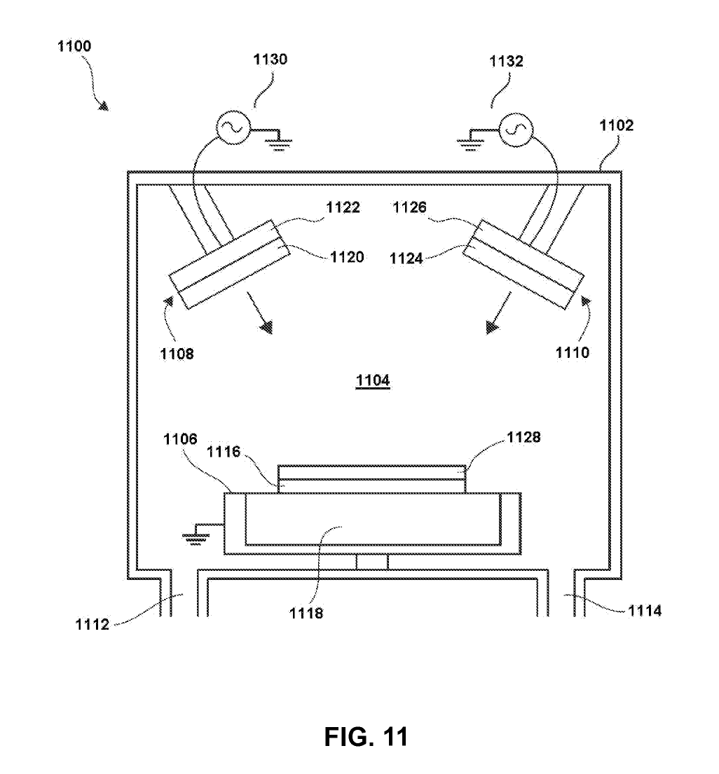

FIG. 11 provides a simplified illustration of a physical vapor deposition (PVD) tool (and/or system) 1100 which may be used, in some embodiments, to form an IGZO layer (and/or other components of the IGZO device) described above. The PVD tool 1100 shown in FIG. 11 includes a housing 1102 that defines, or encloses, a processing chamber 1104, a substrate support 1106, a first target assembly 1108, and a second target assembly 1110.

The housing 1102 includes a gas inlet 1112 and a gas outlet 1114 near a lower region thereof on opposing sides of the substrate support 1106. The substrate support 1106 is positioned near the lower region of the housing 1102 and in configured to support a substrate 1116. The substrate 1116 may be a round substrate having a diameter of, for example, about 200 mm or about 300 mm. In other embodiments (such as in a manufacturing environment), the substrate 1116 may have other shapes, such as square or rectangular, and may be significantly larger (e.g., about 0.5 to about 4 m across). The substrate support 1106 includes a support electrode 1118 and is held at ground potential during processing, as indicated.

The first and second target assemblies (or process heads) 1108 and 1110 are suspended from an upper region of the housing 1102 within the processing chamber 1104. The first target assembly 1108 includes a first target 1120 and a first target electrode 1122, and the second target assembly 1110 includes a second target 1124 and a second target electrode 1126. As shown, the first target 1120 and the second target 1124 are oriented or directed towards the substrate 1116. As is commonly understood, the first target 1120 and the second target 1124 include one or more materials that are to be used to deposit a layer of material 1128 on the upper surface of the substrate 1116.

The materials used in the targets 1120 and 1124 may, for example, include indium, gallium, tin, zinc, tin, silicon, silver, aluminum, manganese, molybdenum, zirconium, hathium, titanium, molybdenum, copper, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although only two targets 1120 and 1124 are shown, additional targets may be used.

The PVD tool 1100 also includes a first power supply 1130 coupled to the first target electrode 1122 and a second power supply 1132 coupled to the second target electrode 1124. As is commonly understood, in some embodiments, the power supplies 1130 and 1132 pulse direct current (DC) power to the respective electrodes, causing material to be, at least in some embodiments, simultaneously sputtered (i.e., co-sputtered) from the first and second targets 1120 and 1124. In some embodiments, the power is alternating current (AC) to assist in directing the ejected material towards the substrate 1116.

During sputtering, inert gases (or a plasma species), such as argon or krypton, may be introduced into the processing chamber 1104 through the gas inlet 1112, while a vacuum is applied to the gas outlet 1114. The inert gas(es) may be used to impact the targets 1120 and 1124 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 11, the PVD tool 1100 may also include a control system having, for example, a processor and a memory, which is in operable communication with the other components shown in FIG. 11 and configured to control the operation thereof in order to perform the methods described herein.

As described above, in some embodiments, during the formation (or deposition) of the IGZO, the pressure within the processing chamber 1104 of the PVD tool 1100 is maintained at less than about 5 mT, such as between about 1 mT and about 5 mT. In some embodiments, the oxygen incorporation rate within the processing chamber 1104 is maintained at between about 20% and about 100% during the deposition process. In some embodiments, the duty cycle of the PVD process is maintained between about 70% and 100%. In some embodiments, the temperature within the processing chamber 1104 is maintained between room temperature (e.g., about 25° C.) and about 400° C. These processing conditions may be used individually, or in any combination thereof.

Although the PVD tool 1100 shown in FIG. 11 includes a stationary substrate support 1106, it should be understood that in a manufacturing environment, the substrate 1116 may be in motion (e.g., an in-line configuration) during the formation of various layers described herein.

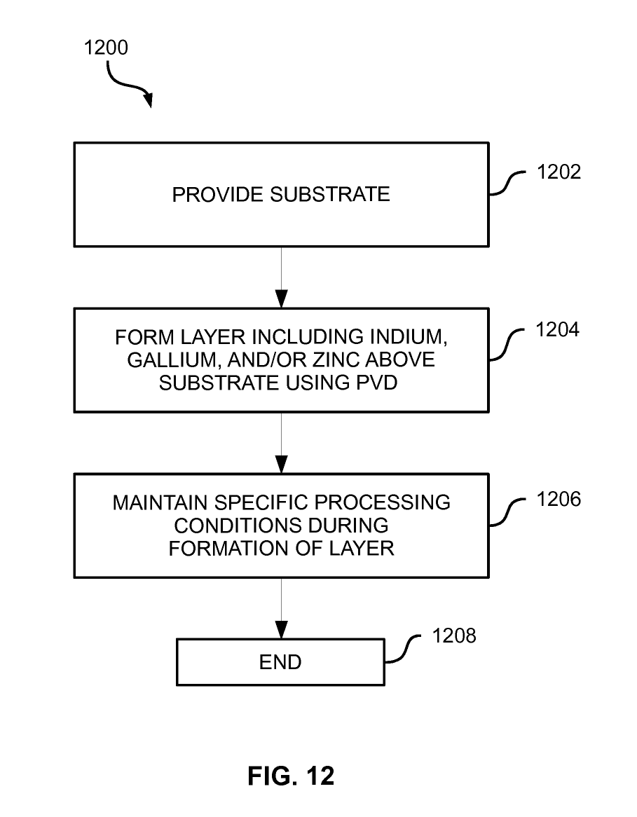

FIG. 12 illustrates a method 1200 for forming crystalline IGZO (or enhancing the crystalline structure of IGZO) according to some embodiments. At block 1202, the method 1000 begins with a substrate being provided. In some embodiments, the substrate is positioned on a substrate support in a PVD tool processing chamber that has at least one target positioned therein. The at least one target includes indium gallium, zinc, or a combination thereof. As described above, the substrate may be made of glass.

At block 1204, a layer including indium, gallium, zinc, or a combination thereof is formed above the substrate using a PVD process, such as sputtering. The layer may be made of IGZO. As described above, the PVD process may include causing material to be ejected from at least one target (e.g., indium, gallium, zinc, or a combination thereof) and deposited above the substrate.

At block 1206, specific processing conditions are maintained during the PVD process used to form (or deposit) the layer. In some embodiments, during the formation (or deposition) of the layer, the pressure within the processing chamber of the PVD tool is maintained at less than about 5 mT, such as between about 1 mT and about 5 mT. In some embodiments, the oxygen incorporation rate within the processing chamber is maintained at between about 20% and about 100% during the deposition process. In some embodiments, the duty cycle of the PVD process is maintained between about 70% and 100%. In some embodiments, the temperature within the processing chamber is maintained between room temperature (e.g., about 25° C.) and about 400° C. During the formation of the layer, these processing conditions may be used individually, or in any combination thereof.

In some embodiments, the layer is formed as a component (e.g., an IGZO channel layer) in an IGZO device, such as an IGZO TFT. As such, although not shown, in some embodiments, the method 1200 includes the formation of additional components of an IGZO device, such as the gate electrode, gate dielectric layer, source/drain regions, etc. At block 1208, the method 1200 ends.

Thus, in some embodiments, a method is provided. A substrate is provided. A layer is formed above the substrate using a PVD process. The layer includes indium, gallium, zinc, or a combination thereof. The PVD process is performed in a gaseous environment having a pressure of between about 1 mT and about 5 mT and including between about 20% and about 100% oxygen gas.

In some embodiments, a method for forming an IGZO) device is provided. A substrate is provided. An IGZO layer is formed above the substrate using a PVD process. The PVD process is performed in a gaseous environment having a pressure of between about 1 mT and about 5 mT and including between about 20% and about 100% oxygen gas and at a processing temperature between about 25° C. and about 400° C.

In some embodiments, a method for forming an IGZO device is provided. A substrate is provided. The substrate is positioned relative to at least one target including indium, gallium, zinc, or a combination thereof. The substrate and the at least one target are exposed to a gaseous environment having a pressure of between about 1 mT and about 5 mT, including between about 20% and about 100% oxygen gas, and having a temperature of between about 25° C. and about 400° C. Material is caused to be ejected from the at least one target to form an IGZO layer above the substrate. The causing of the material to be ejected from the at least one target includes providing a negative charge and a non-negative charge to the at least one target in an alternating manner.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method comprising:
providing a substrate; and
forming a layer above the substrate using a physical vapor deposition (PVD) process, wherein the layer comprises indium, gallium, zinc, or a combination thereof,
wherein the PVD process is performed in a gaseous environment having a pressure of between about 1 millitorr (mT) and about 5 mT and comprising between about 20% and about 100% oxygen gas.

2. The method of claim 1, wherein the PVD process is performed at a processing temperature between about 25° C. and about 400° C.

3. The method of claim 1, wherein the forming of the layer comprises causing material to be ejected from at least one target, the at least one target comprising indium, gallium, zinc, or a combination thereof, and further comprising providing a negative charge and a non-negative charge to the at least one target in an alternating manner.

4. The method of claim 3, wherein the providing the negative charge and the non-negative charge to the at least one target comprises providing the negative charge to the at least one target for between about 70% and about 100% of the time.

5. The method of claim 1, further comprising forming a gate electrode above the substrate, wherein the layer is formed above the gate electrode.

6. The method of claim 5, further comprising forming a gate dielectric layer above the gate electrode, wherein the layer is formed above the gate dielectric layer.

7. The method of claim 6, further comprising forming a source region and a drain region above the layer.

8. The method of claim 7, further comprising forming a passivation layer above the source region and the drain region.

9. A method for forming an indium-gallium-zinc oxide (IGZO) device, the method comprising:
providing a substrate; and
forming an IGZO layer above the substrate using a physical vapor deposition (PVD) process,
wherein the PVD process is performed in a gaseous environment having a pressure of between about 1 millitorr (mT) and about 5 mT and comprising between about 20% and about 100% oxygen gas and at a processing temperature between about 25° C. and about 400° C.

10. The method of claim 9, wherein the forming of the IGZO layer comprises causing material to be ejected from at least one target, the at least one target comprising indium, gallium, zinc, or a combination thereof, and further comprising providing a negative charge and a non-negative charge to the at least one target in an alternating manner.

11. The method of claim 9, wherein the providing the negative charge and the non-negative charge to the at least one target comprises providing the negative charge to the at least one target for between about 70% and about 100% of the time.

12. The method of claim 9, further comprising forming a gate electrode above the substrate, wherein the IGZO layer is formed above the gate electrode.

13. The method of claim 12, further comprising forming a gate dielectric layer above the gate electrode, wherein the IGZO layer is formed above the gate dielectric layer.

14. The method of claim 13, further comprising forming a source region and a drain region above the IGZO layer.

15. The method of claim 14, further comprising forming a passivation layer above the source region and the drain region.

16. A method for forming an indium-gallium-zinc oxide (IGZO) device, the method comprising:
providing a substrate;
positioning the substrate relative to at least one target comprising indium, gallium, zinc, or a combination thereof;
exposing the substrate and the at least one target to a gaseous environment having a pressure of between about 1 millitorr (mT) and about 5 mT and comprising between about 20% and about 100% oxygen gas and a temperature between about 25° C. and about 400° C.; and
causing material to be ejected from the at least one target to form an IGZO layer above the substrate, wherein the causing of the material to be ejected from the at least one target comprises providing a negative charge and a non-negative charge to the at least one target in an alternating manner.

17. The method of claim 16, wherein the providing the negative charge and the non-negative charge to the at least one target comprises providing the negative charge to the at least one target for between about 70% and about 100% of the time.

18. The method of claim 17, further comprising forming a gate electrode above the substrate, wherein the IGZO layer is formed above the gate electrode.

19. The method of claim 18, further comprising forming a gate dielectric layer above the gate electrode, wherein the IGZO layer is formed above the gate dielectric layer.

20. The method of claim 19, further comprising:
forming a source region and a drain region above the IGZO layer; and
forming a passivation layer above the source region and the drain region.
